(19) United States
(12) Patent Application Publication
(10) Pub. No.: US 2026/0068179 A1
(43) Pub. Date: Mar. 5, 2026

(54) SIGNAL TRANSMISSION SYSTEM INCLUDING MULTIPLE PHYSICAL INTERFACES

(71) Applicant: SK hynix Inc., Icheon-si (KR)

(72) Inventor: Choung Ki SONG, Icheon-si (KR)

(73) Assignee: SK hynix Inc., Icheon-si (KR)

(21) Appl. No.: 19/001,022

(22) Filed: Dec. 24, 2024

(30) Foreign Application Priority Data
Sep. 2, 2024 (KR) 10-2024-0118862

(51) Int. Cl. H10B 80/00; H01L 25/065; H01L 25/18

(52) U.S. Cl. CPC H10B 80/00

(57) ABSTRACT

A signal transmission system includes a base chip and a memory chip that are vertically stacked through a through silicon via (TSV). The base chip includes a TSV interface circuit that is electrically connected to the TSV. The base chip outputs a command and data that control an operation of the memory chip through the TSV interface circuit. The TSV is disposed in an edge area of the memory chip. The TSV interface circuit is disposed in an edge area of the base chip.

### CROSS-REFERENCE TO RELATED APPLICATION

The present application claims priority under 35 U.S.C. § 119(a) to Korean Patent Application No. 10-2024-0118862, filed in the Korean Intellectual Property Office on Sep. 2, 2024, the entire contents of which application is incorporated herein by reference.

### BACKGROUND

The present disclosure relates to a signal transmission system in which an interface of a base chip that is connected to a through silicon via (TSV) of a memory chip is disposed in an edge area.

As a technology for manufacturing a semiconductor device is developed, a packaging technology for a plurality of core chips for implementing the semiconductor device accomplishes high integration and high performance. In packaging technologies for implementing the semiconductor device, a technology relating to a three-dimensional structure in which a plurality of core chips is vertically stacked, like high bandwidth memory (HBM), compared to the two-dimensional structure in which a plurality of core chips is flatly disposed on a printed circuit board (PCB) is variously developed.

A semiconductor device includes various intellectual properties (IPs) and may perform various operations. Such various IPs may be electrically connected through a network-on-chip (NoC). The NoC is one of the methods of connecting several IPs within the NoC. In the existing case, a connection method using a bus is commonly used. However, as the integrated technology of a semiconductor device is developed, more IPs may be included in the semiconductor device having the same size, and thus, the bus-based method causes a bottleneck phenomena. Accordingly, in the NoC, the concept of a network is also introduced into a connection between IPs within a semiconductor device as if computers are connected to the Internet over a network.

### SUMMARY

In an embodiment, a signal transmission system may include a base chip and a memory chip that are vertically stacked through a through silicon via (TSV). The base chip may include a TSV interface circuit that is electrically connected to the TSV. The base chip may output a command and data that control an operation of the memory chip through the TSV interface circuit. The TSV may be disposed in an edge area of the memory chip. The TSV interface circuit may be disposed in an edge area of the base chip.

In an embodiment, a signal transmission system may include a base chip and a memory chip that are vertically stacked through a first through silicon via (TSV) and a second TSV. The base chip may include a first TSV interface circuit that is electrically connected to the first TSV and a second TSV interface circuit that is electrically connected to the second TSV. The base chip may output first and second commands and first and second data that control an operation of the memory chip through the first and second TSV interface circuits. The first and second TSVs may be disposed in first and second edge areas of the memory chip. The first and second TSV interface circuits may be disposed in first and second edge areas of the base chip.

In an embodiment, a signal transmission system may include a base chip and a memory chip that are vertically stacked through a through silicon via (TSV). The base chip may include a first memory interface circuit configured to receive first and second commands and first and second data from an external device and configured to output the first and second commands and the first and second data, a second memory interface circuit configured to receive the second command and the second data from the first memory interface circuit and configured to output the second command and the second data to the external device, and a TSV interface circuit electrically connected to the TSV. The base chip may output the first command and the first data to the TSV through the TSV interface circuit. The TSV may be disposed in an edge area of the memory chip. The first and second memory interface circuits may be disposed in first and second side areas of the base chip. The TSV interface circuit may be disposed in an edge area of the base chip.

In an embodiment, a signal transmission system may include a base chip and a memory chip that are vertically stacked through a first through silicon via (TSV) and a second TSV. The base chip may include first and second memory interface circuits configured to receive first and second commands and first and second data from an external device and configured to output the first and second commands and the first and second data, and first and second TSV interface circuits that are electrically connected to the first and second TSVs. The base chip may output the first and second commands and the first and second data that control an operation of the memory chip through the first and second TSV interface circuits. The first and second TSVs may be disposed in first and second edge areas of the memory chip. The first and second memory interface circuits may be disposed in a side area of the base chip. The first and second TSV interface circuits may be disposed in first and second edge areas of the base chip.

### BRIEF DESCRIPTION OF THE DRAWINGS

FIG. 1 is a block diagram illustrating a construction of a signal transmission system according to an embodiment of the present disclosure.

FIG. 2 is a block diagram illustrating a connection relationship between a system chip and a base chip that are included in the signal transmission system as illustrated in FIG. 1 and a construction according to a first embodiment of the system chip and the base chip.

FIG. 3 is a block diagram illustrating a construction according to an embodiment of a memory chip that is included in the signal transmission system as illustrated in FIG. 1.

FIG. 4 is a block diagram illustrating a connection relation between the system chip and the base chip that are included in the signal transmission system as illustrated in FIG. 1 and a construction according to a second embodiment of the system chip and the base chip.

FIG. 5 is a block diagram illustrating a connection relation between the system chip and the base chip that are included in the signal transmission system as illustrated in FIG. 1 and a construction according to a third embodiment of the system chip and the base chip.

FIG. 6 is a block diagram illustrating a connection relation between the system chip and the base chip that are included in the signal transmission system as illustrated in FIG. 1 and a construction according to a fourth embodiment of the system chip and the base chip.

FIG. 7 is a block diagram illustrating a connection relation between the system chip and the base chip that are included in the signal transmission system as illustrated in FIG. 1 and a construction according to a fifth embodiment of the system chip and the base chip.

FIG. 8 is a diagram illustrating a construction according to an embodiment of a stack memory system to which the signal transmission system as illustrated in FIGS. 1 to 7 has been applied.

### DETAILED DESCRIPTION

In the descriptions of the following embodiments, the term “preset” indicates that the numerical value of a parameter is previously decided, when the parameter is used in a process or algorithm. According to an embodiment, the numerical value of the parameter may be set when the process or algorithm is started or while the process or algorithm is performed.

Terms such as “first” and “second,” which are used to distinguish among various components, are not limited by the components. For example, a first component may be referred to as a second component, and vice versa.

Terms such as “top”, “bottom”, “left”, and “right”, are merely used to distinguish various components based on a specific orientation of the embodiments. Based on the orientation of the embodiments, the terms may vary.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

Hereafter, the present disclosure will be described in more detail through embodiments. The embodiments are only used to exemplify the present disclosure, and the scope of the present disclosure is not limited by the embodiments.

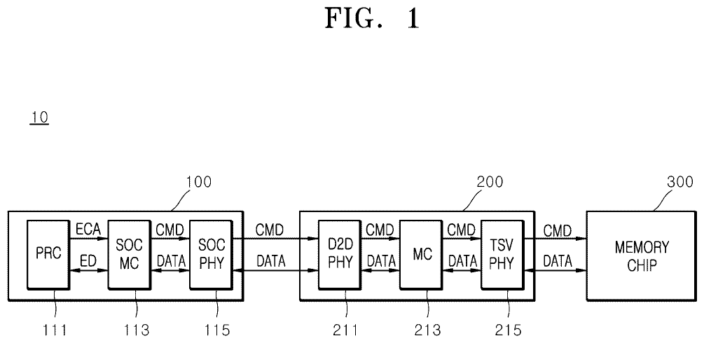

As illustrated in FIG. 1, a signal transmission system 10 may include a system chip 100, a base chip 200, and a memory chip 300.

The system chip 100 may include a processor (PRC) 111, a system controller (SOC MC) 113, and a system interface circuit (SOC PHY) 115.

The processor 111 may generate an external command ECA and external data ED that control an operation of the memory chip 300, based on an external signal that is received from outside of the signal transmission system 10. The external command ECA may be set as a signal including a command and an address that control operations of the memory chip 300, such as an active operation, a write operation, a read operation, and a precharge operations. The external data ED may be set as a signal to be stored in the memory chip 300. The processor 111 may receive the external data ED from the system controller 113 and may output the received external data ED to a device external to the signal transmission system 10. The external signal may be received from a device (e.g., various devices, such as a host HOST and a test device) external to the signal transmission system 10.

The system controller 113 may generate a command CMD and data DATA that control operations of the memory chip 300, such as an active operation, a write operation, a read operation, and a precharge operations, based on the external command ECA and the external data ED that are received from the processor 111. The system controller 113 may output the command CMD and the data DATA to the system interface circuit 115. The system controller 113 may receive the data DATA from the system interface circuit 115.

The system interface circuit 115 may include a plurality of interfaces. The system interface circuit 115 may output the command CMD and the data DATA to the base chip 200. The system interface circuit 115 may receive the data DATA from a memory interface circuit (D2D PHY) 211 and may output the received data DATA to the system controller 113. The system interface circuit 115 may be implemented with a physical layer (PHY) that is responsible for the generation, transmission, and reception of signals and data and is responsible for a physical connection between the system chip 100 and the base chip 200.

The system controller 113 and the system interface circuit 115 may input and output the command CMD and the data DATA in parallel.

The system chip 100 may generate a signal that controls an operation of the memory chip 300, based on an external signal that is received from outside of the signal transmission system 10. The system chip 100 may output a signal that controls an operation of the memory chip 300 to the base chip 200. The system chip 100 may be set as a common system on chip (SoC).

The base chip 200 may include the memory interface circuit 211, a memory controller (MC) 213, and a TSV interface circuit (TSV PHY) 215.

The memory interface circuit 211 may receive the command CMD and the data DATA from the system interface circuit 115. The memory interface circuit 211 may receive data DATA from the memory controller 213 and may output the received data DATA to the system interface circuit 115. The memory interface circuit 211 may be implemented with a physical layer (PHY) that is responsible for the generation, transmission, and reception of signals and is responsible for a physical connection between the system chip 200 and the base chip 200.

The system interface circuit 115 and the memory interface circuit 211 may input and output the command CMD and the data DATA in parallel.

The memory controller 213 may receive the command CMD and the data DATA from the memory interface circuit 211. The memory controller 213 may control an operation of the memory chip 300 based on the received command CMD and data DATA. The memory controller 213 may receive data DATA from the TSV interface circuit 215 and may output the received data DATA to the memory interface circuit 211. The memory controller 213 may be responsible for a role in maximizing efficiency of a memory layer structure and optimizing performance of the memory chip 300 by managing the transmission of data between the system chip 100 and the base chip 200. The memory controller 213 may perform a role in converting a logical address that is generated by the processor 111 into a physical address, a role in controlling an operation of storing data in the memory chip 300, and a role in controlling an operation of outputting data stored in the memory chip 300. Furthermore, the memory controller 213 may perform a role in controlling the parallel processing of data in order to improve a memory bandwidth, a role in increasing the stability of a memory system by detecting and modifying an error of data, and a role in guaranteeing efficient communication between the system chip 10 and the memory chip 300 by controlling the time at which a memory cell that is included in the memory chip 300 is accessed.

The TSV interface circuit 215 may be responsible for the transmission and reception of signals and data through a through silicon via (TSV) of the memory chip 300. The TSV interface circuit 215 may be controlled by the memory controller 213. The TSV interface circuit 215 may transmit a command CMD and data DATA for a write operation on the memory chip 300 through the TSV and may receive data DATA through the TSV during a read operation on the memory chip 300. The TSV interface circuit 215 may receive data DATA from the memory chip 300 and may output the received data DATA to the memory controller 213.

The system chip 100 and the base chip 200 may input and output the command CMD and the data DATA in parallel.

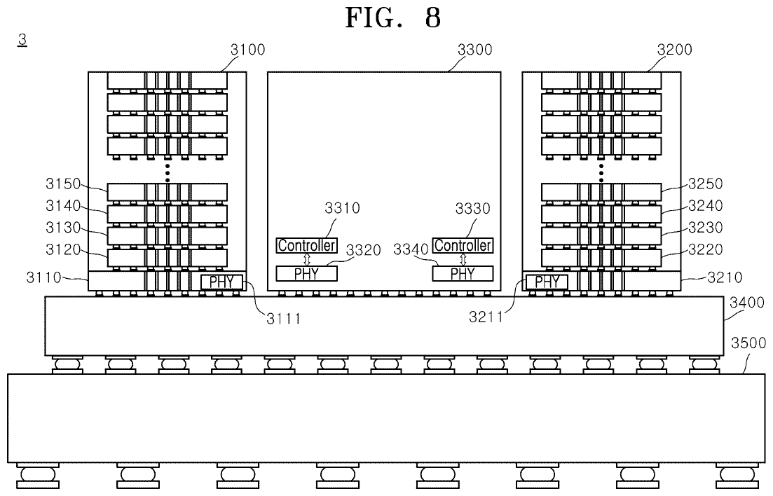

The memory chip 300 may be stacked on or over the base chip 200. The memory chip 300 may include a plurality of core chips, for example, core chips 3120, 3130, 3140, 3150, 3220, 3230, 3140, and 3150 in FIG. 8. The number L of core chips may be one of 4, 8, 12, and so on, but this is merely an embodiment, and the present disclosure is not limited thereto. A through silicon via (TSV) may be formed in the memory chip 300 and the base chip 200. The TSV is a structure that enables an electrical connection through the memory chip 300 and the base chip 200 and plays an important role in allowing signals and data to be transmitted between the memory chip 300 and the base chip 200 at a high speed. The command CMD and the data DATA may be input and output in serial within the memory chip 300.

The system chip 100 and the base chip 200 may each be stacked on or over an interposer 3400 as illustrated in FIG. 8. The system chip 100 and the base chip 200 may input and output the command CMD and the data DATA in serial through variously formed wires that are included in the interposer 3400.

The base chip 200 and the memory chip 300 may each be vertically stacked through micro bumps, like a first stack memory device 3100 as illustrated in FIG. 8.

The plurality of core chips of the memory chip 300, for example, the core chips 3120, 3130, 3140, 3150, 3220, 3230, 3140, and 3150 in FIG. 8, may be vertically stacked through micro bumps.

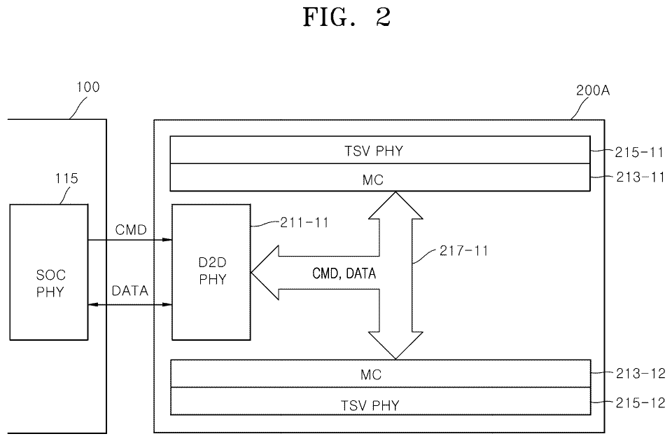

FIG. 2 is a block diagram illustrating a connection relationship between the system chip 100 and the base chip 200 that are included in the signal transmission system 10 as illustrated in FIG. 1 and a construction according to a first embodiment of the system chip and the base chip. A base chip 200A may include a memory interface circuit (D2D PHY) 211-11, a first memory controller (MC) 213-11, a second memory controller (MC) 213-12, a first TSV interface circuit (TSV PHY) 215-11, a second TSV interface circuit (TSV PHY) 215-12, and a transmission path 217-11.

The system interface circuit 115 of the system chip 100 may output a command CMD and data DATA to the memory interface circuit 211-11. The system interface circuit 115 and the memory interface circuit 211-11 may input and output the command CMD and the data DATA in parallel.

The memory interface circuit 211-11 may be disposed in a side area of the base chip 200A. The memory interface circuit 211-11 may receive the command CMD and the data DATA from the system interface circuit 115 of the system chip 100. The memory interface circuit 211-11 may output the received command CMD and data DATA to the transmission path 217-11. The side area of the base chip 200A may be set as an area near an edge of the base chip 200A. Specifically, the side area of the base chip 200A may be set near an edge that is orthogonal to first and second edge areas of the base chip 200A.

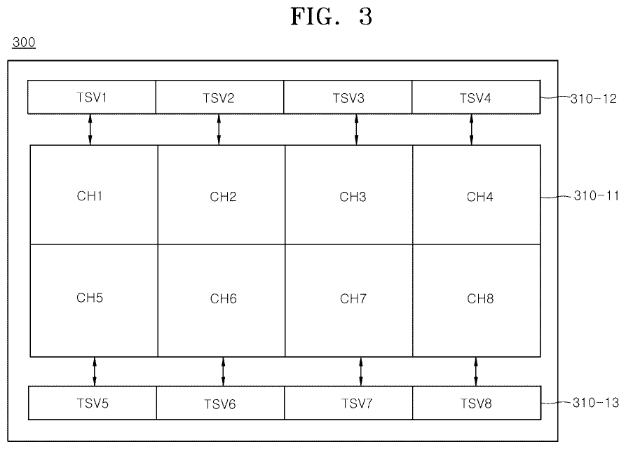

The first memory controller 213-11 may be disposed in the first edge area of the base chip 200A. The first memory controller 213-11 may receive the command CMD and the data DATA from the transmission path 217-11. The first memory controller 213-11 may output the received command CMD and data DATA to the first TSV interface circuit 215-11 in order to control an operation of the memory chip 300. The first memory controller 213-11 may output the received command CMD and data DATA to the first TSV interface circuit 215-11 by classifying the received command CMD and data DATA in order to control operations of a plurality of channels that is included in the memory chip 300, for example, channels CH1 to CH4 in FIG. 3. For example, when receiving a command CMD and data DATA for a write operation of the first channel CH1 of the memory chip 300, the first memory controller 213-11 may output the command CMD and the data DATA to the first TSV interface circuit 215-11 that is connected to a first TSV of the first channel CH1, that is, TSV1 in FIG. 3. Based on the orientation of FIG. 2, the first edge area of the base chip 200A may be set near a top edge of the base chip 200A. The first edge area of the base chip 200A may be set near an edge that is orthogonal to the side area.

The first TSV interface circuit 215-11 may be disposed in the first edge area of the base chip 200A. The first TSV interface circuit 215-11 may be electrically connected to the memory chip 300 through a TSV. The first TSV interface circuit 215-11 may receive the command CMD and the data DATA through the first memory controller 213-11. The first TSV interface circuit 215-11 may output the received command CMD and data DATA to TSVs of the memory chip 300, for example, TSV1 to TSV4 in FIG. 3. For example, when receiving a command CMD and data DATA for a write operation of the first channel CH1 of the memory chip 300, the first TSV interface circuit 215-11 may output the command CMD and the data DATA to the first TSV of the first channel CH1, that is, TSV1 in FIG. 3.

The second memory controller 213-12 may be disposed in the second edge area of the base chip 200A. The second memory controller 213-12 may receive a command CMD and data DATA through the transmission path 217-11. The second memory controller 213-12 may output the received command CMD and data DATA to the second TSV interface circuit 215-12 in order to control an operation of the memory chip 300. The second memory controller 213-12 may output the received command CMD and data DATA to the second TSV interface circuit 215-12 by classifying the received command CMD and data DATA in order to control operations of a plurality of channels that is included in the memory chip 300, for example, channels CH5 to CH8 in FIG. 3. For example, when receiving a command CMD and data DATA for a write operation of the eighth channel CH8 of the memory chip 300, the second memory controller 213-12 may output the command CMD and the data DATA to the second TSV interface circuit 215-12 that is connected to an eighth TSV of the eighth channel CH8, that is, TSV8 in FIG. 3. Based on the orientation of FIG. 2, the second edge area of the base chip 200A may be set near a bottom edge of the base chip 200A. The second edge area of the base chip 200A may be set near an edge that is orthogonal to the side area.

The second TSV interface circuit 215-12 may be disposed in the second edge area of the base chip 200A. The second TSV interface circuit 215-12 may be electrically connected to the memory chip 300 through a TSV. The second TSV interface circuit 215-12 may receive a command CMD and data DATA through the second memory controller 213-12. The second TSV interface circuit 215-12 may output the received command CMD and data DATA to TSVs of the memory chip 300, for example, TSV5 to TSV8 in FIG. 3. For example, when receiving a command CMD and data DATA for a write operation of the eighth channel CH8 of the memory chip 300, the second TSV interface circuit 215-12 may output the command CMD and the data DATA to the eighth TSV of the eighth channel CH8, that is, TSV8 in FIG. 3.

The transmission path 217-11 may be disposed between the first memory controller 213-11 and the second memory controller 213-12 from the memory interface circuit 211-11. The transmission path 217-11 may be disposed in the first edge area of the base chip 200A from the side area of the base chip 200A. The transmission path 217-11 may be disposed in the second edge area of the base chip 200A from the side area of the base chip 200A. The transmission path 217-11 may be implemented with an NoC. The NoC may be set as a transmission path that connects various modules within a chip. The transmission path 217-11 may receive the command CMD and the data DATA from the memory interface circuit 211-11 and may output the command CMD and the data DATA to the first memory controller 213-11. The transmission path 217-11 may receive the command CMD and the data DATA from the memory interface circuit 211-11 and may output the command CMD and the data DATA to the second memory controller 213-12.

FIG. 3 is a block diagram illustrating a construction according to an embodiment of the memory chip 300 that is included in the signal transmission system 10 as illustrated in FIG. 1. The memory chip 300 may include a channel area 310-11, a first TSV area 310-12, and a second TSV area 310-13. The channel area 310-11 may include the first to eighth channels CH1 to CH8. The channel area 310-11 may store the data DATA after the start of a write operation based on a command CMD. The channel area 310-11 may output data DATA that have been stored in the channel area 310-11, after the start of a read operation, based on a command CMD. The channel area 310-11 may be disposed in a central area of the memory chip 300.

The first TSV area 310-12 may include the first to fourth TSVs TSV1 to TSV4. After the start of a write operation and a read operation, the first TSV area 310-12 may receive a command CMD and may output the command CMD to the channel area 310-11. After the start of a write operation, the first TSV area 310-12 may receive data DATA and may output the data DATA to the channel area 310-11. After the start of a read operation, the first TSV area 310-12 may receive data DATA from the channel area 310-11 and may output the data DATA to the first TSV interface circuit 215-11. The first TSV area 310-12 may be disposed in a first edge area of the memory chip 300. The first edge area of the memory chip 300 may be set near a top edge of the memory chip 300 and may be centered around the center of the channel area 310-11. The first edge area of the memory chip 300 and the first edge area of the base chip 200A may be vertically aligned. Each of the first to fourth TSVs TSV1 to TSV4 may include a plurality of TSVs.

The second TSV area 310-13 may include the fifth to eighth TSVs TSV5 to TSV8. After the start of a write operation and a read operation, the second TSV area 310-13 may receive a command CMD and may output the command CMD to the channel area 310-11. After the start of a write operation, the second TSV area 310-13 may receive data DATA and may output the data DATA to the channel area 310-11. After the start of a read operation, the second TSV area 310-13 may receive data DATA from the channel area 310-11 and may output the data DATA to the second TSV interface circuit 215-12. The second TSV area 310-13 may be disposed in a second edge area of the memory chip 300. The second edge area of the memory chip 300 may be set near a bottom edge of the memory chip 300 and may be be centered around the channel area 310-11. The second edge area of the memory chip 300 and the second edge area of the base chip 200A may be vertically aligned. Each of the fifth to eighth TSVs TSV5 to TSV8 may include a plurality of TSVs.

The first channel CH1 may be electrically connected to the first TSV TSV1 and may input and output a command CMD and data DATA. The second channel CH2 may be electrically connected to the second TSV TSV2 and may input and output a command CMD and data DATA. The third channel CH3 may be electrically connected to the third TSV TSV3 and may input and output a command CMD and data DATA. The fourth channel CH4 may be electrically connected to the fourth TSV TSV4 and may input and output a command CMD and data DATA. The fifth channel CH5 may be electrically connected to the fifth TSV TSV5 and may input and output a command CMD and data DATA. The sixth channel CH6 may be electrically connected to the sixth TSV TSV6, and may input and output a command CMD and data DATA. The seventh channel CH7 may be electrically connected to the seventh TSV TSV7 and may input and output a command CMD and data DATA. The eighth channel CH8 may be electrically connected to the eighth TSV TSV8 and may input and output a command CMD and data DATA.

The channel area 310-11, first TSV area 310-12, and second TSV area 310-13 of the memory chip 300 may input and output the command CMD and the data DATA in serial.

As described above, in the signal transmission system 10 according to an embodiment of the present disclosure, circuits that are included in the base chip 200A can be efficiently connected because the interface of the base chip 200A that is connected to the TSV of the memory chip 300 is disposed in the edge area. In the signal transmission system 10, various internal circuits can be disposed in the base chip 200A because the interface included in the base chip 200A is disposed in the edge area.

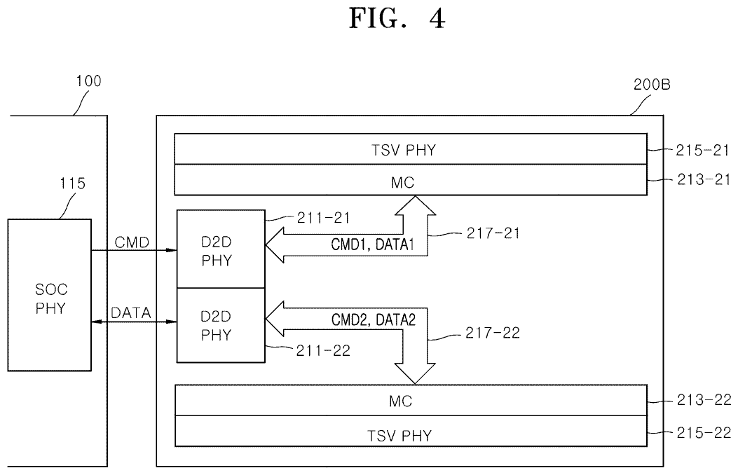

FIG. 4 is a block diagram illustrating a connection relation between the system chip 100 and the base chip 200 that are included in the signal transmission system 10 as illustrated in FIG. 1 and a construction according to a second embodiment of the system chip and the base chip. A base chip 200B may include a first memory interface circuit (D2D PHY) 211-21, a second memory interface circuit (D2D PHY) 211-22, a first memory controller (MC) 213-21, a second memory controller (MC) 213-22, a first TSV interface circuit (TSV PHY) 215-21, a second TSV interface circuit (TSV PHY) 215-22, a first transmission path 217-21, and a second transmission path 217-22.

The system interface circuit 115 of the system chip 100 may output a command CMD and data DATA to the first memory interface circuit 211-21. The system interface circuit 115 and the first memory interface circuit 211-21 may input and output the command CMD and the data DATA in parallel.

The system interface circuit 115 of the system chip 100 may output a command CMD and data DATA to the second memory interface circuit 211-22. The system interface circuit 115 and the second memory interface circuit 211-22 may input and output the command CMD and the data DATA in parallel.

The first memory interface circuit 211-21 may be disposed in a side area of the base chip 200B. The first memory interface circuit 211-21 may receive the command CMD and the data DATA from the system interface circuit 115 of the system chip 100. The first memory interface circuit 211-21 may output the received command CMD and data DATA to the first transmission path 217-21. The side area of the base chip 200B may be set near an edge of the base chip 200B. Specifically, the side area of the base chip 200B may be set near an edge that is orthogonal to first and second edge areas of the base chip 200B.

The second memory interface circuit 211-22 may be disposed in the side area of the base chip 200B. The second memory interface circuit 211-22 may receive the command CMD and the data DATA from the system interface circuit 115 of the system chip 100. The second memory interface circuit 211-22 may output the received command CMD and data DATA to the second transmission path 217-22.

The first memory controller 213-21 may be disposed in the first edge area of the base chip 200B. The first memory controller 213-21 may receive a command CMD and data DATA through the first transmission path 217-21. The first memory controller 213-21 may output the received command CMD and data DATA to the first TSV interface circuit 215-21 in order to control an operation of the memory chip 300. The first memory controller 213-21 may output the received command CMD and data DATA to the first TSV interface circuit 215-21 by classifying the received command CMD and data DATA in order to control operations of a plurality of channels that is included in the memory chip 300, for example, CH1 to CH4 in FIG. 3. For example, when receiving a command CMD and data DATA for a write operation of the first channel CH1 of the memory chip 300, the first memory controller 213-21 may output the command CMD and the data DATA to the first TSV interface circuit 215-21 that is connected to the first TSV of the first channel CH1, that is, TSV1 in FIG. 3. Based on the orientation of FIG. 4, the first edge area of the base chip 200B may be set near a top edge of the base chip 200B. The first edge area of the base chip 200B may be set near an edge that is orthogonal to the side area.

The first TSV interface circuit 215-21 may be disposed in the first edge area of the base chip 200B. The first TSV interface circuit 215-21 may be electrically connected to the memory chip 300 through a TSV. The first TSV interface circuit 215-21 may receive the command CMD and the data DATA through the first memory controller 213-21. The first TSV interface circuit 215-21 may output the received command CMD and data DATA to TSVs of the memory chip 300, for example, TSV1 to TSV4 in FIG. 3. For example, when receiving a command CMD and data DATA for a write operation of the first channel CH1 of the memory chip 300, the first TSV interface circuit 215-21 may output the command CMD and the data DATA to the first TSV that is connected to the first channel CH1, that is, TSV1 in FIG. 3.

The second memory controller 213-22 may be disposed in the second edge area of the base chip 200B. The second memory controller 213-22 may receive a command CMD and data DATA through the second transmission path 217-22. The second memory controller 213-22 may output the received command CMD and data DATA to the second TSV interface circuit 215-22 in order to control an operation of the memory chip 300. The second memory controller 213-22 may output the received command CMD and data DATA to the second TSV interface circuit 215-22 by classifying the received command CMD and data DATA in order to control operations of a plurality of channels that is included in the memory chip 300, for example, CH5 to CH8 in FIG. 3. For example, when receiving a command CMD and data DATA for a write operation of the eighth channel CH8 of the memory chip 300, the second memory controller 213-22 may output the command CMD and the data DATA to the second TSV interface circuit 215-22 that is connected to the eighth TSV of the eighth channel CH8, that is, TSV8 in FIG. 3. Based on the orientation of FIG. 4, the second edge area of the base chip 200B may be set near a bottom edge of the base chip 200B. The second edge area of the base chip 200B may be set near an edge that is orthogonal to the side area.

The second TSV interface circuit 215-22 may be disposed in the second edge area of the base chip 200B. The second TSV interface circuit 215-22 may be electrically connected to the memory chip 300 through a TSV. The second TSV interface circuit 215-22 may receive the command CMD and data DATA through the second memory controller 213-22. The second TSV interface circuit 215-22 may output the received command CMD and data DATA to TSVs of the memory chip 300, for example, TSV5 to TSV8 in FIG. 3. For example, when receiving a command CMD and data DATA for a write operation of the eighth channel CH8 of the memory chip 300, the second TSV interface circuit 215-22 may output the command CMD and the data DATA to the eighth TSV that is connected to the eighth channel CH8, that is, TSV8 in FIG. 3.

The first transmission path 217-21 may be disposed between the first memory interface circuit 211-21 and the first memory controller 213-21. The first transmission path 217-21 may be disposed in the first edge area of the base chip 200B from the side area of the base chip 200B. The first transmission path 217-21 may be implemented with an NoC. The first transmission path 217-21 may receive the command CMD and the data DATA from the first memory interface circuit 211-21 and may output the command CMD and the data DATA to the first memory controller 213-21.

The second transmission path 217-22 may be disposed between the second memory interface circuit 211-22 and the second memory controller 213-22. The second transmission path 217-22 may be disposed in the second edge area of the base chip 200B from the side area of the base chip 200B. The second transmission path 217-22 may be implemented with an NoC. The second transmission path 217-22 may receive the command CMD and the data DATA from the second memory interface circuit 211-22 and may output the command CMD and the data DATA to the second memory controller 213-22.

As described above, in the signal transmission system 10 according to an embodiment of the present disclosure, circuits that are included in the base chip 200B can be efficiently connected because the interfaces of the base chip 200B that are connected to the TSV of the memory chip 300 are disposed in the edge area. In the signal transmission system 10, various internal circuits can be disposed in the base chip 200B because the interfaces included in the base chip 200B are disposed in the edge area.

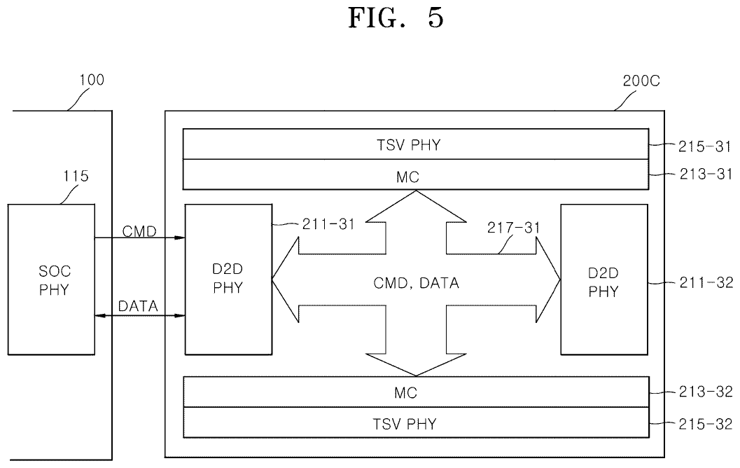

FIG. 5 is a block diagram illustrating a connection relation between the system chip 100 and the base chip 200 that are included in the signal transmission system 10 as illustrated in FIG. 1 and a construction according to a third embodiment of the system chip and the base chip. A base chip 200C may include a first memory interface circuit (D2D PHY) 211-31, a second memory interface circuit (D2D PHY) 211-32, a first memory controller (MC) 213-31, a second memory controller (MC) 213-32, a first TSV interface circuit (TSV PHY) 215-31, a second TSV interface circuit (TSV PHY) 215-32, and a transmission path 217-31.

The system interface circuit 115 of the system chip 100 may output a command CMD and data DATA to the first memory interface circuit 211-31. The system interface circuit 115 and the first memory interface circuit 211-31 may input and output the command CMD and the data DATA in parallel.

The first memory interface circuit 211-31 may be disposed in a first side area of the base chip 200C. The first memory interface circuit 211-31 may receive the command CMD and the data DATA from the system interface circuit 115 of the system chip 100. The first memory interface circuit 211-31 may output the received command CMD and data DATA to the transmission path 217-31. Based on the orientation of FIG. 5, the first side area of the base chip 200C may be set near a left edge of the base chip 200C. The first side area of the base chip 200C may be set near an edge that is orthogonal to first and second edge areas of the base chip 200C.

The second memory interface circuit 211-32 may be disposed in a second side area of the base chip 200C. The second memory interface circuit 211-32 may receive a command CMD and data DATA from the transmission path 217-31. The second memory interface circuit 211-32 may output the received command CMD and data DATA to an external device. Based on the orientation of FIG. 5, the second side area of the base chip 200C may be set near a right edge of the base chip 200C. The second side area of the base chip 200C may be set near an edge that is orthogonal to the first and second edge areas of the base chip 200C. The external device may be implemented with other system chips and other memory chips according to an embodiment of the present disclosure.

The first memory controller 213-31 may be disposed in the first edge area of the base chip 200C. The first memory controller 213-31 may receive a command CMD and data DATA through the transmission path 217-31. The first memory controller 213-31 may output the received command CMD and data DATA to the first TSV interface circuit 215-31 in order to control an operation of the memory chip 300. The first memory controller 213-31 may output the received command CMD and data DATA to the first TSV interface circuit 215-31 by classifying the received command CMD and data DATA in order to control operations of a plurality of channels that is included in the memory chip 300, for example, CH1 to CH4 in FIG. 3. For example, when receiving a command CMD and data DATA for a write operation of the first channel CH1 of the memory chip 300, the first memory controller 213-31 may output the command CMD and the data DATA to the first TSV interface circuit 215-31 that is connected to the first TSV of the first channel CH1, that is, TSV1 in FIG. 3. Based on the orientation of FIG. 5, the first edge area of the base chip 200C may be set near a top edge of the base chip 200C. The first edge area of the base chip 200C may be set near an edge that is orthogonal to the first and second side areas.

The first TSV interface circuit 215-31 may be disposed in the first edge area of the base chip 200C. The first TSV interface circuit 215-31 may be electrically connected to the memory chip 300 through a TSV. The first TSV interface circuit 215-31 may receive the command CMD and the data DATA through the first memory controller 213-31. The first TSV interface circuit 215-31 may output the received command CMD and data DATA to TSVs of the memory chip 300, for example, TSV1 to TSV4 in FIG. 3. For example, when receiving a command CMD and data DATA for a write operation of the first channel CH1 of the memory chip 300, the first TSV interface circuit 215-31 may output the command CMD and the data DATA to the first TSV that is connected to the first channel CH1, that is, TSV1 in FIG. 3.

The second memory controller 213-32 may be disposed in the second edge area of the base chip 200C. The second memory controller 213-32 may receive the command CMD and the data DATA through the transmission path 217-31. The second memory controller 213-32 may output the received command CMD and data DATA to the second TSV interface circuit 215-32 in order to control an operation of the memory chip 300. The second memory controller 213-32 may output the received command CMD and data DATA to the second TSV interface circuit 215-32 by classifying the received command CMD and data DATA in order to control operations of a plurality of channels that is included in the memory chip 300, for example, CH5 to CH8 in FIG. 3. For example, when receiving a command CMD and data DATA for a write operation of the eighth channel CH8 of the memory chip 300, the second memory controller 213-32 may output the command CMD and the data DATA to the second TSV interface circuit 215-32 that is connected to the eighth TSV of the eighth channel CH8, that is, TSV8 in FIG. 3. Based on the orientation of FIG. 5, the second edge area of the base chip 200C may be set near a bottom edge of the base chip 200C. The second edge area of the base chip 200C may be set near an edge that is orthogonal to the first and second side areas.

The second TSV interface circuit 215-32 may be disposed in the second edge area of the base chip 200C. The second TSV interface circuit 215-32 may be electrically connected to the memory chip 300 through a TSV. The second TSV interface circuit 215-32 may receive the command CMD and the data DATA through the second memory controller 213-32. The second TSV interface circuit 215-32 may output the received command CMD and data DATA to TSVs of the memory chip 300, for example, TSV5 to TSV8 in FIG. 3. For example, when receiving a command CMD and data DATA for a write operation of the eighth channel CH8 of the memory chip 300, the second TSV interface circuit 215-32 may output the command CMD and the data DATA to the eighth TSV that is connected to the eighth channel CH8, that is, TSV8 in FIG. 3.

The transmission path 217-31 may be disposed between the first memory controller 213-31, the second memory controller 213-32, and the second memory interface circuit 211-32 from the first memory interface circuit 211-31. The transmission path 217-31 may be disposed in the first edge area of the base chip 200C from the first side area of the base chip 200C. The transmission path 217-31 may be disposed in the second edge area of the base chip 200C from the first side area of the base chip 200C. The transmission path 217-31 may be disposed in the second side area of the base chip 200C from the first side area of the base chip 200C. The transmission path 217-31 may be implemented with an NoC. The NoC may be set as a transmission path that connects various modules within a chip. The transmission path 217-31 may receive the command CMD and the data DATA from the first memory interface circuit 211-31 and may output the command CMD and the data DATA to the first memory controller 213-31. The transmission path 217-31 may receive the command CMD and the data DATA from the first memory interface circuit 211-31 and may output the command CMD and the data DATA to the second memory controller 213-32. The transmission path 217-31 may receive the command CMD and the data DATA from the first memory interface circuit 211-31 and may output the command CMD and the data DATA to the second memory interface circuit 211-32.

As described above, in the signal transmission system 10 according to an embodiment of the present disclosure, circuits that are included in the base chip 200C can be efficiently connected because the interfaces of the base chip 200C that are connected to the TSV of the memory chip 300 are disposed in the edge areas. In the signal transmission system 10, various internal circuits can be disposed in the base chip 200C because the interfaces included in the base chip 200C are disposed in the edge areas.

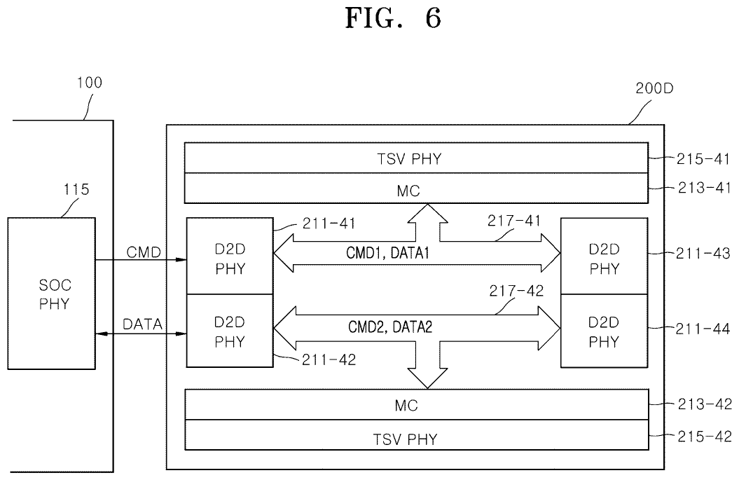

FIG. 6 is a block diagram illustrating a connection relation between the system chip 100 and the base chip 200 that are included in the signal transmission system 10 as illustrated in FIG. 1 and a construction according to a fourth embodiment of the system chip and the base chip. A base chip 200D may include a first memory interface circuit (D2D PHY) 211-41, a second memory interface circuit (D2D PHY) 211-42, a third memory interface circuit (D2D PHY) 211-43, a fourth memory interface circuit (D2D PHY) 211-44, a first memory controller (MC) 213-41, a second memory controller (MC) 213-42, a first TSV interface circuit (TSV PHY) 215-41, a second TSV interface circuit (TSV PHY) 215-42, a first transmission path 217-41, and a second transmission path 217-42.

The system interface circuit 115 of the system chip 100 may output a command CMD and data DATA to the first memory interface circuit 211-41. The system interface circuit 115 and the first memory interface circuit 211-41 may input and output the command CMD and the data DATA in parallel. The system interface circuit 115 of the system chip 100 may output a command CMD and data DATA to the second memory interface circuit 211-42. The system interface circuit 115 and the second memory interface circuit 211-42 may input and output the command CMD and the data DATA in parallel.

The first memory interface circuit 211-41 may be disposed in a first side area of the base chip 200D. The first memory interface circuit 211-41 may receive a first command CMD1 and first data DATA1 from the system interface circuit 115 of the system chip 100. The first memory interface circuit 211-41 may output the received first command CMD1 and first data DATA1 to the first transmission path 217-41. Based on the orientation of FIG. 6, the first side area of the base chip 200D may be set near a left edge of the base chip 200D. The first side area of the base chip 200D may be set near an edge that is orthogonal to first and second edge areas of the base chip 200D.

The second memory interface circuit 211-42 may be disposed in the first side area of the base chip 200D. The second memory interface circuit 211-42 may receive a second command CMD2 and second data DATA2 from the system interface circuit 115 of the system chip 100. The second memory interface circuit 211-42 may output the received second command CMD2 and second data DATA2 to the second transmission path 217-42.

The third memory interface circuit 211-43 may be disposed in a second side area of the base chip 200D. The third memory interface circuit 211-43 may receive the first command CMD1 and the first data DATA1 from the first transmission path 217-41. The third memory interface circuit 211-43 may output the received first command CMD1 and first data DATA1 to an external device. Based on the orientation of FIG. 6, the second side area of the base chip 200D may be set near a right edge of the base chip 200D. The second side area of the base chip 200D may be set near an edge that is orthogonal to the first and second edge areas of the base chip 200D. The external device may be implemented with other system chips and other memory chips according to an embodiment of the present disclosure.

The fourth memory interface circuit 211-44 may be disposed in the second side area of the base chip 200D. The fourth memory interface circuit 211-44 may receive the second command CMD2 and the second data DATA2 from the second transmission path 217-42. The fourth memory interface circuit 211-44 may output the received second command CMD2 and second data DATA2 to the external device.

The first memory controller 213-41 may be disposed in the first edge area of the base chip 200D. The first memory controller 213-41 may receive the first command CMD1 and the first data DATA1 through the first transmission path 217-41. The first memory controller 213-41 may output the received first command CMD1 and first data DATA1 to the first TSV interface circuit 215-41 in order to control an operation of the memory chip 300. The first memory controller 213-41 may output the received first command CMD1 and first data DATA1 to the first TSV interface circuit 215-41 by classifying the received first command CMD1 and first data DATA1 in order to control operations of a plurality of channels that is included in the memory chip 300, for example, CH1 to CH4 in FIG. 3. For example, when receiving the first command CMD1 and the first data DATA1 for a write operation of the first channel CH1 of the memory chip 300, the first memory controller 213-41 may output the first command CMD1 and the first data DATA1 to the first TSV interface circuit 215-41 that is connected to the first TSV of the first channel CH1, that is, TSV1 in FIG. 3. Based on the orientation of FIG. 6, the first edge area of the base chip 200D may be set near a top edge of the base chip 200D. The first edge area of the base chip 200D may be set near an edge that is orthogonal to the first and second side areas.

The first TSV interface circuit 215-41 may be disposed in the first edge area of the base chip 200D. The first TSV interface circuit 215-41 may be electrically connected to the memory chip 300 through a TSV. The first TSV interface circuit 215-41 may receive the first command CMD1 and the first data DATA1 through the first memory controller 213-41. The first TSV interface circuit 215-41 may output the received first command CMD1 and first data DATA1 to TSVs of the memory chip 300, for example, TSV1 to TSV4 in FIG. 3. For example, when receiving the first command CMD1 and the first data DATA1 for a write operation of the first channel CH1 of the memory chip 300, the first TSV interface circuit 215-41 may output the first command CMD1 and the first data DATA1 to the first TSV that is connected to the first channel CH1, that is, TSV1 in FIG. 3.

The second memory controller 213-42 may be disposed in the second edge area of the base chip 200D. The second memory controller 213-42 may receive the second command CMD2 and the second data DATA2 through the second transmission path 217-42. The second memory controller 213-42 may output the received second command CMD2 and second data DATA2 to the second TSV interface circuit 215-42 in order to control an operation of the memory chip 300. The second memory controller 213-42 may output the received second command CMD2 and second data DATA2 to the second TSV interface circuit 215-42 by classifying the received second command CMD2 and second data DATA2 in order to control operations of a plurality of channels that is included in the memory chip 300, for example, CH5 to CH8 in FIG. 3. For example, when receiving the second command CMD2 and the second data DATA2 for a write operation of the eighth channel CH8 of the memory chip 300, the second memory controller 213-42 may output the second command CMD2 and the second data DATA2 to the second TSV interface circuit 215-42 that is connected to the eighth TSV of the eighth channel CH8, that is, TSV8 in FIG. 3. Based on the orientation of FIG. 6, the second edge area of the base chip 200D may be set near a bottom edge of the base chip 200D. The second edge area of the base chip 200D may be set near an edge that is orthogonal to the first and second side areas.

The second TSV interface circuit 215-42 may be disposed in the second edge area of the base chip 200D. The second TSV interface circuit 215-42 may be electrically connected to the memory chip 300 through a TSV. The second TSV interface circuit 215-42 may receive the second command CMD2 and the second data DATA2 through the second memory controller 213-42. The second TSV interface circuit 215-42 may output the received second command CMD2 and second data DATA2 to TSVs of the memory chip 300, for example, TSV5 to TSV8 in FIG. 3. For example, when receiving the second command CMD2 and the second data DATA2 for a write operation of the eighth channel CH8 of the memory chip 300, the second TSV interface circuit 215-42 may output the second command CMD2 and the second data DATA2 to the eighth TSV that is connected to the eighth channel CH8, that is, TSV8 in FIG. 3.

The first transmission path 217-41 may be disposed between the first memory controller 213-41 and the third memory interface circuit 211-43 from the first memory interface circuit 211-41. The first transmission path 217-41 may be disposed in the first edge area of the base chip 200D from the first side area of the base chip 200D. The first transmission path 217-41 may be disposed in the second side area of the base chip 200D from the first side area of the base chip 200D. The first transmission path 217-41 may be implemented with an NoC. The NoC may be set as a transmission path that connects various modules within a chip. The first transmission path 217-41 may receive the first command CMD1 and the first data DATA1 from the first memory interface circuit 211-41 and may output the first command CMD1 and the first data DATA1 to the first memory controller 213-41. The first transmission path 217-41 may receive the first command CMD1 and the first data DATA1 from the first memory interface circuit 211-41 and may output the first command CMD1 and the first data DATA1 to the third memory interface circuit 211-43.

The second transmission path 217-42 may be disposed between the second memory controller 213-42 and the fourth memory interface circuit 211-44 from the second memory interface circuit 211-42. The second transmission path 217-42 may be disposed in the second edge area of the base chip 200D from the first side area of the base chip 200D. The second transmission path 217-42 may be disposed in the second side area of the base chip 200D from the first side area of the base chip 200D. The second transmission path 217-42 may be implemented with an NoC. The second transmission path 217-42 may receive the second command CMD2 and the second data DATA2 from the second memory interface circuit 211-42 and may output the second command CMD2 and the second data DATA2 to the second memory controller 213-42. The second transmission path 217-42 may receive the second command CMD2 and the second data DATA2 from the second memory interface circuit 211-42 and may output the second command CMD2 and the second data DATA2 to the fourth memory interface circuit 211-44.

As described above, in the signal transmission system 10 according to an embodiment of the present disclosure, circuits that are included in the base chip 200D can be efficiently connected because the interfaces of the base chip 200D that are connected to the TSV of the memory chip 300 are disposed in the edge areas. In the signal transmission system 10, various internal circuits can be disposed in the base chip 200D because the interfaces included in the base chip 200D are disposed in the edge areas.

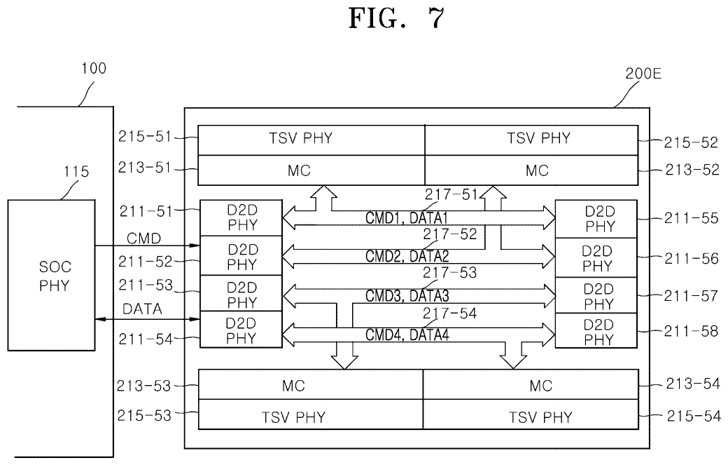

FIG. 7 is a block diagram illustrating a connection relation between the system chip 100 and the base chip 200 that are included in the signal transmission system 10 as illustrated in FIG. 1 and a construction according to a fifth embodiment of the system chip and the base chip. A base chip 200E may include a first memory interface circuit (TSV PHY) 211-51, a second memory interface circuit (TSV PHY) 211-52, a third memory interface circuit (D2D PHY) 211-53, a fourth memory interface circuit (D2D PHY) 211-54, a fifth memory interface circuit (D2D PHY) 211-55, a sixth memory interface circuit (D2D PHY) 211-56, a seventh memory interface circuit (D2D PHY) 211-57, an eighth memory interface circuit (D2D PHY) 211-58, a first memory controller (MC) 213-51, a second memory controller (MC) 213-52, a third memory controller (MC) 213-53, a fourth memory controller (MC) 213-54, a first TSV interface circuit (TSV PHY) 215-51, a second TSV interface circuit (TSV PHY) 215-52, a third TSV interface circuit (TSV PHY) 215-53, a fourth TSV interface circuit (TSV PHY) 215-54, a first transmission path 217-51, a second transmission path 217-52, a third transmission path 217-53, and a fourth transmission path 217-54.

The system interface circuit 115 of the system chip 100 may output a command CMD and data DATA to the first memory interface circuit 211-51. The system interface circuit 115 and the first memory interface circuit 211-51 may input and output the command CMD and the data DATA in parallel.

The system interface circuit 115 of the system chip 100 may output the command CMD and the data DATA to the second memory interface circuit 211-52. The system interface circuit 115 and the second memory interface circuit 211-52 may input and output the command CMD and the data DATA in parallel.

The system interface circuit 115 of the system chip 100 may output a command CMD and data DATA to the third memory interface circuit 211-53. The system interface circuit 115 and the third memory interface circuit 211-53 may input and output the command CMD and the data DATA in parallel.

The system interface circuit 115 of the system chip 100 may output a command CMD and data DATA to the fourth memory interface circuit 211-54. The system interface circuit 115 and the fourth memory interface circuit 211-54 may input and output the command CMD and the data DATA in parallel.

The first memory interface circuit 211-51 may be disposed in a first side area of the base chip 200E. The first memory interface circuit 211-51 may receive a first command CMD1 and first data DATA1 from the system interface circuit 115 of the system chip 100. The first memory interface circuit 211-51 may output the received first command CMD1 and first data DATA1 to the first transmission path 217-51. Based on the orientation of FIG. 7, the first side area of the base chip 200E may be set near a left edge of the base chip 200E. The first side area of the base chip 200E may be set near an edge that is orthogonal to first and second edge areas of the base chip 200E.

The second memory interface circuit 211-52 may be disposed in the first side area of the base chip 200E. The second memory interface circuit 211-52 may receive a second command CMD2 and second data DATA2 from the system interface circuit 115 of the system chip 100. The second memory interface circuit 211-52 may output the received second command CMD2 and second data DATA2 to the second transmission path 217-52.

The third memory interface circuit 211-53 may be disposed in the first side area of the base chip 200E. The third memory interface circuit 211-53 may receive a third command CMD3 and third data DATA3 from the system interface circuit 115 of the system chip 100. The third memory interface circuit 211-53 may output the received third command CMD3 and third data DATA3 to the third transmission path 217-53.

The fourth memory interface circuit 211-54 may be disposed in the first side area of the base chip 200E. The fourth memory interface circuit 211-54 may receive a fourth command CMD4 and fourth data DATA4 from the system interface circuit 115 of the system chip 100. The fourth memory interface circuit 211-54 may output the received fourth command CMD4 and fourth data DATA4 to the fourth transmission path 217-54.

The fifth memory interface circuit 211-55 may be disposed in a second side area of the base chip 200E. The fifth memory interface circuit 211-55 may receive the first command CMD1 and the first data DATA1 from the first transmission path 217-51. The fifth memory interface circuit 211-55 may output the received first command CMD1 and first data DATA1 to an external device. Based on the orientation of FIG. 7, the second side area of the base chip 200E may be set near a right edge of the base chip 200E. The second side area of the base chip 200E may be set near an edge that is orthogonal to the first and second edge areas of the base chip 200E. The external device may be implemented with other system chips and other memory chips according to an embodiment of the present disclosure.

The sixth memory interface circuit 211-56 may be disposed in the second side area of the base chip 200E. The sixth memory interface circuit 211-56 may receive the second command CMD2 and the second data DATA2 from the second transmission path 217-52. The sixth memory interface circuit 211-56 may output the received second command CMD2 and second data DATA2 to the external device.

The seventh memory interface circuit 211-57 may be disposed in the second side area of the base chip 200E. The seventh memory interface circuit 211-57 may receive the third command CMD3 and the third data DATA3 from the third transmission path 217-53. The seventh memory interface circuit 211-57 may output the received third command CMD3 and third data DATA3 to the external device.

The eighth memory interface circuit 211-58 may be disposed in the second side area of the base chip 200E. The eighth memory interface circuit 211-58 may receive the fourth command CMD4 and the fourth data DATA4 from the fourth transmission path 217-54. The eighth memory interface circuit 211-58 may output the received fourth command CMD4 and fourth data DATA4 to the external device.

The first memory controller 213-51 may be disposed in the first edge area of the base chip 200E. The first memory controller 213-51 may receive the first command CMD1 and the first data DATA1 through the first transmission path 217-51. The first memory controller 213-51 may output the received first command CMD1 and first data DATA1 to the first TSV interface circuit 215-51 in order to control an operation of the memory chip 300. The first memory controller 213-51 may output the received first command CMD1 and first data DATA1 to the first TSV interface circuit 215-51 by classifying the received first command CMD1 and first data DATA1 in order to control operations of a plurality of channels that is included in the memory chip 300, for example, CH1 and CH2 in FIG. 3. For example, when receiving the first command CMD1 and the first data DATA1 for a write operation of the first channel CH1 of the memory chip 300, the first memory controller 213-51 may output the first command CMD1 and the first data DATA1 to the first TSV interface circuit 215-51 that is connected to the first TSV of the first channel CH1, that is, TSV1 in FIG. 3. Based on the orientation of FIG. 7, the first edge area of the base chip 200E may be set near a top edge of the base chip 200E. The first edge area of the base chip 200E may be set near an edge that is orthogonal to the first and second side areas.

The first TSV interface circuit 215-51 may be disposed in the first edge area of the base chip 200E. The first TSV interface circuit 215-51 may be electrically connected to the memory chip 300 through a TSV. The first TSV interface circuit 215-51 may receive the first command CMD1 and the first data DATA1 through the first memory controller 213-51. The first TSV interface circuit 215-51 may output the received first command CMD1 and first data DATA1 to TSVs of the memory chip 300, for example, TSV1 and TSV2 in FIG. 3. For example, when receiving the first command CMD1 and the first data DATA1 for a write operation of the first channel CH1 of the memory chip 300, the first TSV interface circuit 215-51 may output the first command CMD1 and the first data DATA1 to the first TSV that is connected to the first channel CH1, that is, TSV1 in FIG. 3.

The second memory controller 213-52 may be disposed in the first edge area of the base chip 200E. The second memory controller 213-52 may receive the second command CMD2 and the second data DATA2 through the second transmission path 217-52. The second memory controller 213-52 may output the received second command CMD2 and second data DATA2 to the second TSV interface circuit 215-52 in order to control an operation of the memory chip 300. The second memory controller 213-52 may output the received second command CMD2 and second data DATA2 to the second TSV interface circuit 215-52 by classifying the received second command CMD2 and second data DATA2 in order to control operations of a plurality of channels that is included in the memory chip 300, for example, CH3 and CH4 in FIG. 3. For example, when receiving the second command CMD2 and the second data DATA2 for a write operation of the third channel CH3 of the memory chip 300, the second memory controller 213-52 may output the second command CMD2 and the second data DATA2 to the second TSV interface circuit 215-52 that is connected to the third TSV of the third channel CH3, that is, TSV3 in FIG. 3.

The second TSV interface circuit 215-52 may be disposed in the first edge area of the base chip 200E. The second TSV interface circuit 215-52 may be electrically connected to the memory chip 300 through a TSV. The second TSV interface circuit 215-52 may receive the second command CMD2 and the second data DATA2 through the second memory controller 213-52. The second TSV interface circuit 215-52 may output the received second command CMD2 and second data DATA2 to TSVs of the memory chip 300, for example, TSV3 and TSV4 in FIG. 3. For example, when receiving the second command CMD2 and the second data DATA2 for a write operation of the third channel CH3 of the memory chip 300, the second TSV interface circuit 215-52 may output the second command CMD2 and the second data DATA2 to the third TSV that is connected to the third channel CH3, that is, TSV3 in FIG. 3.

The third memory controller 213-53 may be disposed in the second edge area of the base chip 200E. The third memory controller 213-53 may receive the third command CMD3 and the third data DATA3 through the third transmission path 217-53. The third memory controller 213-53 may output the received third command CMD3 and third data DATA3 to the third TSV interface circuit 215-53 in order to control an operation of the memory chip 300. The third memory controller 213-53 may output the received third command CMD3 and third data DATA3 to the third TSV interface circuit 215-53 by classifying the received third command CMD3 and third data DATA3 in order to control operations of a plurality of channels that is included in the memory chip 300, for example, CH5 and CH6 in FIG. 3. For example, when receiving the third command CMD3 and the third data DATA3 for a write operation of the fifth channel CH5 of the memory chip 300, the third memory controller 213-53 may output the third command CMD3 and the third data DATA3 to the third TSV interface circuit 215-53 that is connected to the fifth TSV of the fifth channel CH5, that is, TSV5 in FIG. 3. Based on the orientation of FIG. 7, the second edge area of the base chip 200E may be set near a bottom edge of the base chip 200E. The second edge area of the base chip 200E may be set near an edge that is orthogonal to the first and second side areas.

The third TSV interface circuit 215-53 may be disposed in the second edge area of the base chip 200E. The third TSV interface circuit 215-53 may be electrically connected to the memory chip 300 through a TSV. The third TSV interface circuit 215-53 may receive the third command CMD3 and the third data DATA3 through the third memory controller 213-53. The third TSV interface circuit 215-53 may output the received third command CMD3 and third data DATA3 to TSVs of the memory chip 300, for example, TSV5 and TSV6 in FIG. 3. For example, when receiving the third command CMD3 and the third data DATA3 for a write operation of the fifth channel CH5 of the memory chip 300, the third TSV interface circuit 215-53 may output the third command CMD3 and the third data DATA3 to the fifth TSV that is connected to the fifth channel CH5, that is, TSV5 in FIG. 3.

The fourth memory controller 213-54 may be disposed in the second edge area of the base chip 200E. The fourth memory controller 213-54 may receive the fourth command CMD4 and the fourth data DATA4 through the fourth transmission path 217-54. The fourth memory controller 213-54 may output the received fourth command CMD4 and fourth data DATA4 to the fourth TSV interface circuit 215-54 in order to control an operation of the memory chip 300. The fourth memory controller 213-54 may output the received fourth command CMD4 and fourth data DATA4 to the fourth TSV interface circuit 215-54 by classifying the received fourth command CMD4 and fourth data DATA4 in order to control operations of a plurality of channels that is included in the memory chip 300, for example, CH7 and CH8 in FIG. 3. For example, when receiving the fourth command CMD4 and the fourth data DATA4 for a write operation of the seventh channel CH7 of the memory chip 300, the fourth memory controller 213-54 may output the fourth command CMD4 and the fourth data DATA4 to the fourth TSV interface circuit 215-54 that is connected to the seventh TSV of the seventh channel CH7, that is, TSV7 in FIG. 3.

The fourth TSV interface circuit 215-54 may be disposed in the second edge area of the base chip 200E. The fourth TSV interface circuit 215-54 may be electrically connected to the memory chip 300 through a TSV. The fourth TSV interface circuit 215-54 may receive the fourth command CMD4 and the fourth data DATA4 through the fourth memory controller 213-54. The fourth TSV interface circuit 215-54 may output the received fourth command CMD4 and fourth data DATA4 to TSVs of the memory chip 300, for example, TSV7 and TSV8 in FIG. 3. For example, when receiving the fourth command CMD4 and the fourth data DATA4 for a write operation of the seventh channel CH7 of the memory chip 300, the fourth TSV interface circuit 215-54 may output the fourth command CMD4 and the fourth data DATA4 to the seventh TSV that is connected to the seventh channel CH7, that is, TSV7 in FIG. 3.

The first transmission path 217-51 may be disposed between the first memory controller 213-51 and the fifth memory interface circuit 211-55 from the first memory interface circuit 211-51. The first transmission path 217-51 may be disposed in the first edge area of the base chip 200E from the first side area of the base chip 200E. The first transmission path 217-51 may be disposed in the second side area of the base chip 200E from the first side area of the base chip 200E. The first transmission path 217-51 may be implemented with an NoC. The NoC may be set as a transmission path that connects various modules within a chip. The first transmission path 217-51 may receive the first command CMD1 and the first data DATA1 from the first memory interface circuit 211-51 and may output the first command CMD1 and the first data DATA1 to the first memory controller 213-51. The first transmission path 217-51 may receive the first command CMD1 and the first data DATA1 from the first memory interface circuit 211-51 and may output the first command CMD1 and the first data DATA1 to the fifth memory interface circuit 211-55.

The second transmission path 217-52 may be disposed between the second memory controller 213-52 and the sixth memory interface circuit 211-56 from the second memory interface circuit 211-52. The second transmission path 217-52 may be disposed in the first edge area of the base chip 200E from the first side area of the base chip 200E. The second transmission path 217-52 may be disposed in the second side area of the base chip 200E from the first side area of the base chip 200E. The second transmission path 217-52 may be implemented with an NoC. The second transmission path 217-52 may receive the second command CMD2 and the second data DATA2 from the second memory interface circuit 211-52 and may output the second command CMD2 and the second data DATA2 to the second memory controller 213-52. The second transmission path 217-52 may receive the second command CMD2 and the second data DATA2 from the second memory interface circuit 211-52 and may output the second command CMD2 and the second data DATA2 to the sixth memory interface circuit 211-56.

The third transmission path 217-53 may be disposed between the third memory controller 213-53 and the seventh memory interface circuit 211-57 from the third memory interface circuit 211-53. The third transmission path 217-53 may be disposed in the second edge area of the base chip 200E from the first side area of the base chip 200E. The third transmission path 217-53 may be disposed in the second side area of the base chip 200E from the first side area of the base chip 200E. The third transmission path 217-53 may be implemented with an NoC. The third transmission path 217-53 may receive the third command CMD3 and the third data DATA3 from the third memory interface circuit 211-53 and may output the third command CMD3 and the third data DATA3 to the third memory controller 213-53. The third transmission path 217-53 may receive the third command CMD3 and the third data DATA3 from the third memory interface circuit 211-53 and may output the third command CMD3 and the third data DATA3 to the seventh memory interface circuit 211-57.

The fourth transmission path 217-54 may be disposed between the fourth memory controller 213-54 and the eighth memory interface circuit 211-58 from the fourth memory interface circuit 211-54. The fourth transmission path 217-54 may be disposed in the second edge area of the base chip 200E from the first side area of the base chip 200E. The fourth transmission path 217-54 may be disposed in the second side area of the base chip 200E from the first side area of the base chip 200E. The fourth transmission path 217-54 may be implemented with an NoC. The fourth transmission path 217-54 may receive the fourth command CMD4 and the fourth data DATA4 from the fourth memory interface circuit 211-54 and may output the fourth command CMD4 and the fourth data DATA4 to the fourth memory controller 213-54. The fourth transmission path 217-54 may receive the fourth command CMD4 and the fourth data DATA4 from the fourth memory interface circuit 211-54 and may output the fourth command CMD4 and the fourth data DATA4 to the eighth memory interface circuit 211-58.

As described above, in the signal transmission system 10 according to an embodiment of the present disclosure, circuits that are included in the base chip 200E can be efficiently connected because the interfaces of the base chip 200E that are connected to the TSV of the memory chip 300 are disposed in the edge areas. In the signal transmission system 10, various internal circuits can be disposed in the base chip 200E because the interfaces included in the base chip 200E are disposed in the edge areas.

FIG. 8 is a block diagram illustrating a construction of a stack memory system 3 according to an embodiment of the present disclosure. As illustrated in FIG. 8, the stack memory system 3 may include the first stack memory device 3100, a second stack memory device 3200, a processor 3300, the interposer 3400, and a substrate 3500.

The interposer 3400 may be formed on or over the substrate 3500. The first stack memory device 3100, the second stack memory device 3200, and the processor 3300 may be formed on or over the interposer 3400. The processor 3300 may be formed between the first stack memory device 3100 and the second stack memory device 3200. The interposer 3400 may be used to electrically connect the substrate 3500, the first stack memory device 3100, the second stack memory device 3200, and the processor 3300. The first stack memory device 3100, the second stack memory device 3200, and the processor 3300 may be electrically connected by using the interposer 3400 including variously formed wires because differences between the pitches of the first stack memory device 3100, the second stack memory device 3200, and the processor 3300 are large.

The processor 3300 may include a first controller 3310 that controls the first stack memory device 3100 and a first process interface circuit (PHY) 3320 that electrically connects the first stack memory device 3100 and the first controller 3310. The processor 3300 may include a second controller 3330 that controls the second stack memory device 3200 and a second process interface circuit (PHY) 3340 that electrically connects the second stack memory device 3200 and the second controller 3330. The processor 3300 may apply a signal, including a command and an address that control various internal operations of the first stack memory device 3100, to the first stack memory device 3100 through the first process interface circuit 3320 and may receive a signal from the first stack memory device 3100 through the first process interface circuit 3320. The processor 3300 may apply a signal, including a command and an address that control various internal operations of the second stack memory device 3200, to the second stack memory device 3200 through the second process interface circuit 3340 and may receive a signal from the second stack memory device 3200 through the second process interface circuit 3340. The first controller 3310 and the second controller 3330 may each be implemented with the system controller 113 as illustrated in FIG. 1. The first process interface circuit 3320 and the second process interface circuit 3340 may each be implemented with the system interface circuit 115 as illustrated in FIG. 1.

The first stack memory device 3100 may include a first base chip 3110 and the first core chips 3120, 3130, 3140, and 3150. The first core chips 3120, 3130, 3140, and 3150 may be sequentially stacked on or over the first base chip 3110 and may receive various signals from the first base chip 3110 through TSVs. The first stack memory device 3100 has been formed to include the four first core chips 3120, 3130, 3140, and 3150 but may be formed by stacking various numbers of core chips, such as 4, 8, 16, and so on, according to an embodiment. The first stack memory device 3100 may be implemented with the base chip 200 and the memory chip 300 as illustrated in FIG. 1.

The first base chip 3110 may include a first core interface circuit (PHY) 3111. The first core interface circuit 3111 may be configured to be capable of communicating with the first process interface circuit 3320. The first core interface circuit 3111 may receive a signal from the processor 3300 and may apply, to the processor 3300, signals that are generated by the first core chips 3120, 3130, 3140, and 3150. The first core interface circuit 3111 may be implemented with the memory interface 211 as illustrated in FIG. 1.

The second stack memory device 3200 may include a second base chip 3210 and the second core chips 3220, 3230, 3240, and 3250. The second core chips 3220, 3230, 3240, and 3250 are sequentially stacked on or over the second base chip 3210, and may receive various signals from the second base chip 3210 through TSVs. The second stack memory device 3200 has been formed to include the four second core chips 3220, 3230, 3240, and 3250, but may be formed by stacking various numbers of core chips, such as 4, 8, and 16, according to an embodiment. The second stack memory device 3200 may be implemented with the base chip 200 and the memory chip 300 as illustrated in FIG. 1.

The second base chip 3210 may include a second core interface circuit (PHY) 3211. The second core interface circuit 3211 may be configured to be capable of communicating with the second process interface circuit 3330. The second core interface circuit 3211 may receive a signal from the processor 3300 and may apply, to the processor 3300, signals that are generated by the second core chips 3220, 3230, 3240, and 3250. The second core interface circuit 3211 may be implemented with the memory interface 211 as illustrated in FIG. 1.

The embodiments of the present disclosure have been described so far. A person having ordinary knowledge in the art to which the present invention pertains will understand that the present invention may be implemented in a modified form without departing from an intrinsic characteristic of the present disclosure. Accordingly, the disclosed embodiments should be considered from a descriptive viewpoint, not from a limitative viewpoint. The range of the present disclosure is described in the claims not the aforementioned description, and all differences within an equivalent range thereof should be construed as being included in the present disclosure.

What is claimed is:

1. A signal transmission system comprising:
a base chip and a memory chip that are vertically stacked through a through silicon via (TSV),
wherein the base chip comprises a TSV interface circuit that is electrically connected to the TSV,
wherein the base chip outputs a command and data that control an operation of the memory chip through the TSV interface circuit,
wherein the TSV is disposed in an edge area of the memory chip, and
wherein the TSV interface circuit is disposed in an edge area of the base chip.

2. The signal transmission system of claim 1,
wherein the memory chip comprises a plurality of channels that stores and outputs the data by performing a write operation and a read operation based on the command, and
wherein the edge area of the memory chip is disposed near two sides of the memory chip that are on opposite sides of each other and centered around the plurality of channels.

3. The signal transmission system of claim 1, wherein, in a plan view, a location of the edge area of the base chip in relation to the base chip corresponds to a location of the edge area of the memory chip in relation to the memory chip,
wherein the edge area of the base chip and the edge area of the memory chip are vertically aligned.

4. The signal transmission system of claim 1, wherein the base chip comprises:
a memory interface circuit configured to receive the command and the data and configured to output the command and the data through a first transmission path;
a memory controller configured to receive the command and the data through the first transmission path and configured to output the command and the data to the TSV interface circuit; and
the TSV interface circuit configured to receive the command and the data from the memory controller and configured to output the command and the data to the TSV.

5. The signal transmission system of claim 4,
wherein the memory interface circuit is disposed in a side area of the base chip, the side area being near a side of the base chip other than sides corresponding to the edge area of the base chip,
wherein the first transmission path is disposed in the edge area of the base chip from the side area of the base chip, and
wherein the memory controller is disposed in the edge area of the base chip.

6. The signal transmission system of claim 1, wherein the base chip and the memory chip input and output the command and the data in parallel.

7. The signal transmission system of claim 1, wherein the memory chip inputs and outputs the command and the data in serial through the TSV.

8. The signal transmission system of claim 4, further comprising a system chip configured to input and output the command and the data to and from the base chip,
wherein the system chip comprises a system interface circuit configured to input and output the command and the data.

9. The signal transmission system of claim 8, wherein the system interface circuit and the memory interface circuit input and output the command and the data in parallel.

10. A signal transmission system comprising:
a base chip and a memory chip that are vertically stacked through a first through silicon via (TSV) and a second TSV,
wherein the base chip comprises a first TSV interface circuit that is electrically connected to the first TSV and a second TSV interface circuit that is electrically connected to the second TSV,
wherein the base chip outputs first and second commands and first and second data that control an operation of the memory chip through the first and second TSV interface circuits,
wherein the first and second TSVs are disposed in first and second edge areas of the memory chip, and
wherein the first and second TSV interface circuits are disposed in first and second edge areas of the base chip.

11. The signal transmission system of claim 10,
wherein the memory chip comprises a first channel that stores and outputs the first data by performing a write operation and a read operation based on the first command, and a second channel that stores and outputs the second data by performing the write operation and the read operation based on the second command,
wherein the first edge area of the memory chip is disposed near a first side of the memory chip and centered around the first channel, and
wherein the second edge area of the memory chip is disposed near a second side of the memory chip that is opposite to the first side and centered around the second channel.

12. The signal transmission system of claim 10,
wherein, in a plan view, a location of the first edge area of the base chip in relation to the base chip corresponds to a location of the first edge area of the memory chip in relation to the memory chip,
wherein, in a plan view, a location of the second edge area of the base chip in relation to the base chip corresponds to a location of the second edge area of the memory chip in relation to the memory chip,
wherein the first edge area of the base chip and the first edge area of the memory chip are vertically aligned, and the second edge area of the base chip and the second edge area of the memory chip are vertically aligned.

13. The signal transmission system of claim 10, wherein the base chip comprises:
a first memory interface circuit configured to receive the first command and the first data and configured to output the first command and the first data through a first transmission path;
a second memory interface circuit configured to receive the second command and the second data and configured to output the second command and the second data through a second transmission path;
a first memory controller configured to receive the first command and the first data through the first transmission path and configured to output the first command and the first data to the first TSV interface circuit;
a second memory controller configured to receive the second command and the second data through the second transmission path and configured to output the second command and the second data to the second TSV interface circuit;
the first TSV interface circuit configured to receive the first command and the first data from the first memory controller and configured to output the first command and the first data to the first TSV; and
the second TSV interface circuit configured to receive the second command and the second data from the second memory controller and configured to output the second command and the second data to the second TSV.

14. The signal transmission system of claim 13,
wherein the first and second memory interface circuits are disposed in a side area of the base chip, the side area being near a side of the base chip other than the first and second edge areas of the base chip,
wherein the first transmission path is disposed in the first edge area of the base chip from the side area of the base chip,
wherein the second transmission path is disposed in the second edge area of the base chip from the side area of the base chip,
wherein the first memory controller is disposed in the first edge area of the base chip, and
wherein the second memory controller is disposed in the second edge area of the base chip.

15. A signal transmission system comprising:
a base chip and a memory chip that are vertically stacked through a through silicon via (TSV),
wherein the base chip comprises a first memory interface circuit configured to receive first and second commands and first and second data from an external device and configured to output the first and second commands and the first and second data, a second memory interface circuit configured to receive the second command and the second data from the first memory interface circuit and configured to output the second command and the second data to the external device, and a TSV interface circuit electrically connected to the TSV,
wherein the base chip outputs the first command and the first data to the TSV through the TSV interface circuit,
wherein the TSV is disposed in an edge area of the memory chip,
wherein the first and second memory interface circuits are disposed in first and second side areas of the base chip, and
wherein the TSV interface circuit is disposed in an edge area of the base chip.

16. The signal transmission system of claim 15,
wherein the memory chip comprises a plurality of channels that stores and outputs the first data by performing a write operation and a read operation based on the first command, and
wherein the edge area of the memory chip is disposed near two sides of the memory chip that are on opposite sides of each other and centered around the plurality of channels.

17. The signal transmission system of claim 15,
wherein, in a plan view, a location of the edge area of the base chip in relation to the base chip corresponds to a location of the edge area of the memory chip in relation to the memory chip,
wherein the edge area of the base chip and the edge area of the memory chip are vertically aligned, and
wherein the first and second side areas of the base chip are disposed near sides that are orthogonal to the edge area of the base chip.

18. The signal transmission system of claim 15, wherein the base chip comprises:
the first memory interface circuit configured to receive the first and second commands and the first and second data and configured to output the first and second commands and the first and second data through a transmission path;
the second memory interface circuit configured to receive the second command and the second data and configured to output the second command and the second data to the external device;
a memory controller configured to receive the first command and the first data through the transmission path and configured to output the first command and the first data to the TSV interface circuit; and
the TSV interface circuit configured to receive the first command and the first data from the memory controller and configured to output the first command and the first data to the TSV.

19. The signal transmission system of claim 18, wherein, from the first side area of the base chip, the transmission path is disposed in the edge area of the base chip and the second side area of the base chip.

20. A signal transmission system comprising:
a base chip and a memory chip that are vertically stacked through a first through silicon via (TSV) and a second TSV,
wherein the base chip comprises first and second memory interface circuits configured to receive first and second commands and first and second data from an external device and configured to output the first and second commands and the first and second data and comprises first and second TSV interface circuits that are electrically connected to the first and second TSVs,
wherein the base chip outputs the first and second commands and the first and second data that control an operation of the memory chip through the first and second TSV interface circuits,
wherein the first and second TSVs are disposed in first and second edge areas of the memory chip,
wherein the first and second memory interface circuits are disposed in a side area of the base chip, and
wherein the first and second TSV interface circuits are disposed in first and second edge areas of the base chip.

21. The signal transmission system of claim 20,
wherein the memory chip comprises a first channel that stores and outputs the first data by performing a write operation and a read operation based on the first command, and a second channel that stores and outputs the second data by performing the write operation and the read operation based on the second command,
wherein the first edge area of the memory chip is disposed near a first side of the memory chip and centered around the first channel, and
wherein the second edge area of the memory chip is disposed near a second side of the memory chip that is opposite to the first side and centered around the second channel.

22. The signal transmission system of claim 20,
wherein, in a plan view, a location of the first edge area of the base chip in relation to the base chip corresponds to a location of the first edge area of the memory chip in relation to the memory chip,
wherein, in a plan view, a location of the second edge area of the base chip in relation to the base chip corresponds to a location of the second edge area of the memory chip in relation to the memory chip, and
wherein the first edge area of the base chip and the first edge area of the memory chip are vertically aligned, and the second edge area of the base chip and the second edge area of the memory chip are vertically aligned, and
wherein the side area of the base chip is near a side of the base chip other than sides corresponding to the first and second edge areas of the base chip.

23. The signal transmission system of claim 20, wherein the base chip comprises:
the first memory interface circuit configured to receive the first command and the first data and configured to output the first command and the first data through a first transmission path;
the second memory interface circuit configured to receive the second command and the second data and configured to output the second command and the second data through a second transmission path;
a first memory controller configured to receive the first command and the first data through the first transmission path and configured to output the first command and the first data to the first TSV interface circuit;
a second memory controller configured to receive the second command and the second data through the second transmission path and configured to output the second command and the second data to the second TSV interface circuit;
the first TSV interface circuit configured to receive the first command and the first data from the first memory controller and configured to output the first command and the first data to the first TSV; and
the second TSV interface circuit configured to receive the second command and the second data from the second memory controller and configured to output the second command and the second data to the second TSV.

24. The signal transmission system of claim 23,
wherein, from the first memory interface circuit, the first transmission path is disposed between the first memory interface circuit and the first memory controller,
wherein, from the second memory interface circuit, the second transmission path is disposed between the second memory interface circuit and the second memory controller,
wherein the first memory controller is disposed in the first edge area of the base chip, and
wherein the second memory controller is disposed in the second edge area of the base chip.

25. The signal transmission system of claim 23, wherein the base chip further comprises:
a third memory interface circuit configured to receive the first command and the first data from the first memory interface circuit and configured to output the first command and the first data to the external device; and
a fourth memory interface circuit configured to receive the second command and the second data from the second memory interface circuit and configured to output the second command and the second data to the external device.

26. The signal transmission system of claim 25,
wherein the first transmission path is disposed between the first memory interface circuit, the third memory interface circuit, and the first memory controller, and
wherein the second transmission path is disposed between the second memory interface circuit, the fourth memory interface circuit, and the second memory controller.
